(19) United States
(12) Patent Application Publication
(10) Pub. No.: US 2011/0284047 A1
(43) Pub. Date: Nov. 24, 2011

(54) MULTI-USE CAMPING POT THAT PRODUCES POWER FROM HEAT

(76) Inventors: Joshua Heath Johnson, Arvada, CO (US); Richard Rawdon Lebedda, Fort Collins, CO (US)

(21) Appl. No.: 13/083,560

(22) Filed: Apr. 9, 2011

Related U.S. Application Data
(60) Provisional application No. 61/346,722, filed on May 20, 2010.

(51) Int. Cl. H01L 35/30; F28F 7/00; G05F 1/10; B65D 25/28

(52) U.S. Cl. 136/205; 220/756; 220/759; 165/185; 323/234

(57) ABSTRACT

People often need to recharge batteries for portable electronics in remote locations where there is no electrical grid. One way to recharge these batteries is to harvest energy from a source of heat such as a camping stove using a thermoelectric module. Prior art depicts using a thermoelectric module harvesting energy from a stove and using a pot of water to cool one side of the module. The current invention improves upon prior art by maximizing power output and efficiency, increasing energy and power density, reducing the risk of damaging the thermoelectric module, and providing communication to the electronic device being charged.

### BACKGROUND

People often carry electronic devices into remote locations while camping, backpacking, performing research, or for military action. Often times these electronic devices require the use of batteries, which are heavy and may not last very long. If the batteries are rechargeable, the user may be able to carry a solar panel, fuel cell, or some other energy storage device into the field to recharge the batteries. However, a solar panel is often not a reliable source of energy due to cloud cover, the angle of the sun, shadows, and nightfall. Other energy storage devices like fuel cells often run on a single fuel source like methanol, have a short lifespan, and can be complex and expensive for the average user. These systems typically have mechanical and/or electrical feedback control systems in place to regulate fuel and temperature. However, the feedback control components often add significant weight and complexity to the system. Another option to recharging batteries in the field is to harvest energy from a heat source such as a camping stove by using a thermoelectric module. The current invention intends to provide a lightweight source of reliable energy in the field by harvesting energy from a heat source using a thermoelectric module coupled to a camping pot. The current invention improves upon prior art by maximizing power output and efficiency, increasing energy density and power density, reducing the risk of damaging the thermoelectric module, and providing communication to the electronic device being charged.

### PROBLEM

Prior art depicts using a thermoelectric module harvesting energy from a stove and using a pot of water to cool one side of the module. Although this depiction is similar to the present invention, several problems are evident. The electrical current that is produced by the thermoelectric module must flow through several inches of wire to a Direct Current to Direct Current converter (DC to DC converter) that sits several inches away from the pot and heat source. Because the current is large, significant power losses may be experienced. These wires may also become exposed to the heat source and could be at risk of catching on fire or melting the insulation on the conductor and causing a short circuit. Prior art depicts using a DC to DC converter to output power from the thermoelectric module. However, using a DC to DC converter may not provide the maximum power or maximum efficiency of the thermoelectric module unless specific measures are taken. Another problem is that the prior art simply bolts a metal plate to the pot in order to sandwich the thermoelectric module. However, this does not optimize the thermal conductivity between the heat source and the thermoelectric module, and thus, this decreases the overall efficiency of the system. The reduced efficiency of the system from heat source to electrical output results in lower energy and power density which increases the weight needed to be carried in the field. Mother problem is that the prior art does not inform the user when there are potentially harmful conditions for the thermoelectric device. The thermoelectric module may withstand temperatures upward of 250 Celsius, but temperatures above this will shorten the lifespan of the module. If a heat source is left unchecked or if the pot is left empty, the temperature of the thermoelectric module may start to rise and degrade the module permanently. Lastly, the prior art does not depict the ability to communicate with the devices it is powering. This means the prior art acts as a “dumb” charger or power source. Devices that could benefit from communicating will not be able to do so.

### DETAILED DESCRIPTION OF THE INVENTION

The following detailed description is of the contemplated modes of carrying out exemplary embodiments of the invention. The description is not to be taken in a limiting sense, but is made merely for the purpose of illustrating the general principles of the invention, since the scope of the invention is best defined by the appended claims. Broadly, an embodiment of the present invention generally provides a multi-use camping pot that produces power from heat.

An embodiment of the present invention may use a solid-state thermoelectric module that generates electrical power while the user is heating the contents of the pot using an external heat source or fuel. The device may conserve weight by excluding an automated feedback control system and because it is used both as a cooking utensil and a power generator. Since there are no moving parts, the lifespan of the invention may be long. Due to the low complexity, the cost may be low as well. The present invention solves many problems present in the prior art. The present invention integrates the DC to DC converter into the detachable handle of the pot. This reduces the length of high current-carrying wires which increases the overall efficiency of the system, reduces the risk of fire, and reduces the risk of tripping. The handle may be detachable from the pot using an attachment mechanism. The handle may also house electrical connectors which couple the thermoelectric module to the DC to DC converter input and electrical connectors that couple the DC to DC converter output to an external electronic device. The present invention also solves the problem of maximizing the available power output or efficiency of the thermoelectric module. By operating the DC to DC converter in a voltage limit control and/or current limit control and limiting the output current to the maximum power point of the thermoelectric module, the converter can optimize the power or efficiency of the thermoelectric device. Power point tracking is another method that is commonly used by converters on solar panels and could be implemented by the converter of the present invention to improve output power or efficiency of the thermoelectric module. The present invention also improves upon the prior art by using heat fins on the heat sink in order to increase the thermal conductivity between the heat source and the thermoelectric device. The overall increase in efficiency results in higher energy and power density, which reduces the weight needed to be carried in the field. The present invention also reduces the risk of overheating the thermoelectric device by using a thermocouple to measure the temperature near the thermoelectric module and using logic circuits in the user interface to inform the user when adverse conditions arise. The user interface may also display other important information such as when the electrical power is available or information received by an external electrical device. The present invention also improves upon the prior art by using a communication signal to enable the transfer of information to and from an external electrical device. The communication protocol may be SMBus, PMBus, USB, or some other type of protocol.

As depicted in the figures, an embodiment of a thermoelectric module 1 may include material that converts heat to electricity. The material may include but is not limited to bismuth, telluride, polymers, ceramics, or kapton tape. While there might be no limit to the efficiency, voltage, current, or power of the thermoelectric module, the module may be between 1% and 25% efficient, output 1-15V, output 1-50 A, and output between 1 and 500 W. Other embodiments of a module may be 4-10% efficient, output 0.1-12 volts, 0.001-35 A, 1-50 W. While there might be no limit to the number of thermoelectric modules, the device may have 1-5 modules connected electrically in series, parallel, or a combination of series and parallel connections. Other embodiments may have a single module. The modules may be between 1 inches square and 10 inches square. A thermocouple 2 may include two dissimilar metals that produce a voltage that changes with temperature. An embodiment may include a combination of metals, including but not limited to chromel, alumel, constantan, iron, nicrosil, nisil, platinum, rhodium, copper, tungsten, rhenium, nickel, molybdenum, cobalt, or gold. The direct current-to-direct current (DC to DC) converter 3 may include circuit elements that regulate the input or output voltage and/or current. The DC to DC converter may include any of the known converter topologies including but not limited to buck, boost, buck-boost, flyback, push-pull, single ended primary inductor converter (SEPIC), Cuk, forward, half-bridge, full-bridge, or resonant converters. The converter may be between 0% and 99.9% efficient. The DC to DC converter may be controlled by either analog or digital circuitry including but not limited to analog or mixed signal integrated circuits (ICs), microcontrollers, or field-programmable gate arrays (FPGAs). The connectors 4 may include a body that contains metal contacts used for conducting electricity. The connectors may take a form for conducting electricity and mating with counterpart connectors. The user interface (UI) 5 may include circuits for processing and displaying information to the user and/or a mechanism for the user to enter commands to the electrical system. The UI may include but is not limited to electronic displays, a speaker, logic circuits, microcontrollers, and processors. The UI may display information regarding the operation of the invention and present command options for the user to enter or accept. The UI may also include button(s) that allow the user to enter commands to the electrical system for use in operation of the system. The vessel 6 may include a cup made out of metal that holds material such as liquids, solids, or a combination of the two. The vessel may include metal, such as aluminum, stainless steal, titanium or other alloys. The vessel may take on a number of shapes and sizes but may be between 2 and 12 inches in diameter and between 2 and 12 inches tall. The vessel also may include a handle 8 made of metal or plastic. The handle may have a cavity for the circuitry of the invention and for housing wires and connectors. The handle 8 may be detachable from the vessel. The plate 7 comprises a thin sheet of metal that compresses the thermoelectric module between the plate and the vessel 6. The plate may be comprised of any type of metal but is preferably made of aluminum, stainless steal, titanium or other alloys. The plate may take on a number of shapes and sizes but is preferably round with a diameter between 2 and 12 inches. The plate is preferably between 0.001 inches and 1 inch in thickness. The plate may have holes, slots, threaded holes, threaded studs, dips or other attachment mechanisms for attaching it to the vessel 6. The plate may have heat fins on the bottom for collecting heat. The plate may be attached to the vessel 6 using bolts, nuts, studs, collars, clamps, screws, dips, or any other method for attachment.

An embodiment may include the vessel 6, the thermoelectric module 1, the plate 7, the DC to DC converter 3, and the wiring and connectors 4. Alternate embodiments may include elements that provide additional benefits and features as described above. For example, an embodiment may include a mechanical connection for connecting with a camping stove. This connection may use bolts, nuts, studs, collars, clamps, screws, dips, or any other method for attachment. An embodiment may also include insulative articles that increase the thermal performance such as a rubber or plastic lid, a neoprene cozy around the outside of the vessel 6, or aerogel or ceramic insulation placed between the thermoelectric module 1 and the vessel 6 and plate 7. In an embodiment, the bottom flat part of the vessel 6 may be attached to the plate 7 with the thermoelectric module 1 in between the two. The thermoelectric module 1 may be electrically insulated from the vessel 6 and the plate 7 either by anodizing the vessel 6 and plate 7 or by using anodized metal plates or ceramic plates placed on either side of the thermoelectric module 1. Thermal grease may also be used when attaching each of these components to aid in the conduction of heat. The vessel 6 may be attached to the plate 7 using bolts, nuts, studs, collars, clamps, screws, dips, or any other method for attachment. The thermoelectric module 1 may be connected the DC to DC converter 3 via wire conductors. The DC to DC converter 3 may be connected to the UI 5 and its circuit components via wire. The DC to DC converter 3 and/or UI 5 may be enclosed in the handle 8 of the vessel 6 and connected to the thermoelectric module 1 via a wire and connector. The thermocouple 2 may be situated near the thermoelectric module 1 either on top, on bottom, or to the side of the thermoelectric module 1. The thermocouple 2 may be connected to the circuitry of the UI 5 and alert the user to operating conditions via a display or speaker. The DC to DC converter 3 and the UI 5 may be a part of the same circuit and/or circuit board. The circuits may be arranged next to each other, far apart, or via connectors. The connectors 4 may be used to connect the thermoelectric module 1 to the DC to DC converter 3, the thermoelectric module 1 to the UI 5, the DC to DC converter 3 to the external electrical load, and/or the thermocouple 2 to the UI circuitry 5. An embodiment of the vessel 6 may be filled with material such as water in order to provide a heat sink and a way of regulating the temperature of one side of the thermoelectric module. The bottom of plate 7 may employ heat fins and be placed near a heat source to absorb heat. The heat will travel through the plate 7, through the thermoelectric module 1, and through the vessel 6 to the material in the vessel. The thermoelectric module 1 may convert a certain percentage of the heat into electricity while the rest of the heat energy will be used to heat up the material in the vessel 6. The electrical power may be converted using the DC to DC converter 3 to a regulated output voltage and/or current. The output power may flow through the connector 4 and wiring to the load. The thermocouple 2 may sense the temperature near the thermoelectric module 1 and provide a voltage reading to the logic circuitry of the UI 5. The thermoelectric module 1 may also provide a voltage signal to be used by the UI 5. The UI may use this information to determine if the temperature of the thermoelectric module 1 is too high. If the temperature is too high, the UI may relay the information to the user through either the speaker, the electronic display, or both. The UI may also command the DC to DC converter to shut down or otherwise alter its operation via a communications signal.

To make an embodiment, one could provide the vessel 6 and anodize the bottom flat surface, place thermal grease on the surface, and place the thermoelectric module 1 against the surface. One could then anodize the plate 7 and place thermal grease on the plate. If the plate were stainless steal, one could place an additional anodized plate or ceramic plate against the plate 7 and apply thermal grease to this surface. The plate 7 could then be connected to the vessel 6 via bolts, nuts, studs, collars, clamps, screws, dips, or any other method for attachment. The thermoelectric module 1 could connect to the DC to DC converter 3 and/or the UI circuitry 5 via wiring and/or electrical connectors. The DC to DC converter 3 and UI 5 could be made by building a circuit board or boards and populating the board(s) with the circuit components. The components and wiring could be soldered to the board(s). The connectors could be soldered to the circuit board(s) and/or wiring. The connectors 4 could be attached to the handle 8 of the vessel or placed in line with the wire. The circuit board(s) could be placed in the handle 8 enclosure and attached via bolts, nuts, studs, collars, clamps, screws, dips, or any other method for attachment. The handle 8 could be provided and attached to the vessel 6 via weld, bolts, nuts, studs, collars, clamps, screws, dips, or any other method for attachment. In an embodiment, the thermoelectric module 1, plate 7, circuitry 3 and 5, and connector 4 could all be detachable.

To use an embodiment, a person could first fill the vessel 6 with a material such as water and place it over a source of heat such as a camp fire or camping stove. As the device heats up, electrical power may be available via the output connector 4. Additionally, the material in the vessel, such as water, may heat up. The user could connect his electronic device to the invention via a cable plugged into the connector on the handle 8. When the person handles the invention he/she could place liquid in the vessel and place the invention over a stove or other heat source. The user would then plug in an electrical device to the output of the DC to DC converter via the connectors 4. When the person is done powering his/her electronic equipment or heating the contents of the vessel 6, he/she could move the device off the heat source using the handle. An embodiment could include a mechanism for thermally attaching the plate 7 to a source of heat such as an exhaust pipe, radiator, or engine component in an industrial or automotive application. Embodiments may include a mechanism for compressing and attaching the thermoelectric module to the vessel in order to increase efficiency. It should be understood, of course, that the foregoing relates to exemplary embodiments of the invention and that modifications may be made without departing from the spirit and scope of the invention as set forth in the following claims.

### BRIEF DESCRIPTION OF THE DRAWINGS

FIG. 1 depicts an isometric view of embodiment of the present invention;

FIG. 2 depicts an exploded view of part of embodiment of the present invention;

FIG. 3 depicts an exploded view of embodiment of FIG. 1 partly assembled;

FIG. 4 depicts a detailed isometric view of part of embodiment of FIG. 3; and

FIG. 5 depicts an electrical block diagram of embodiment.

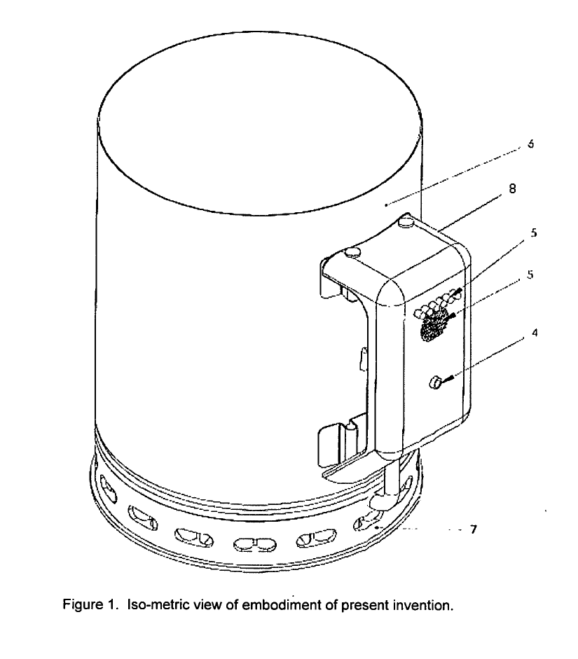

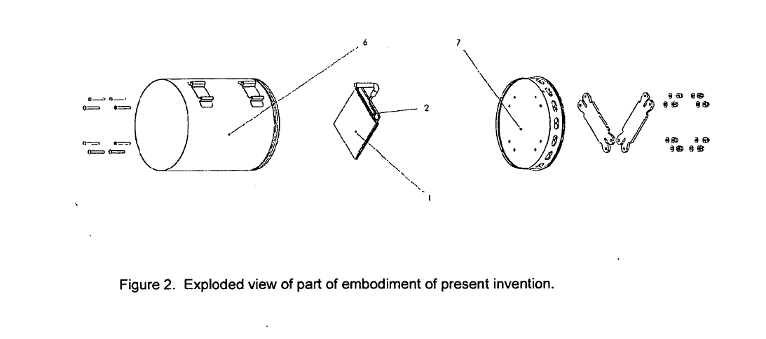

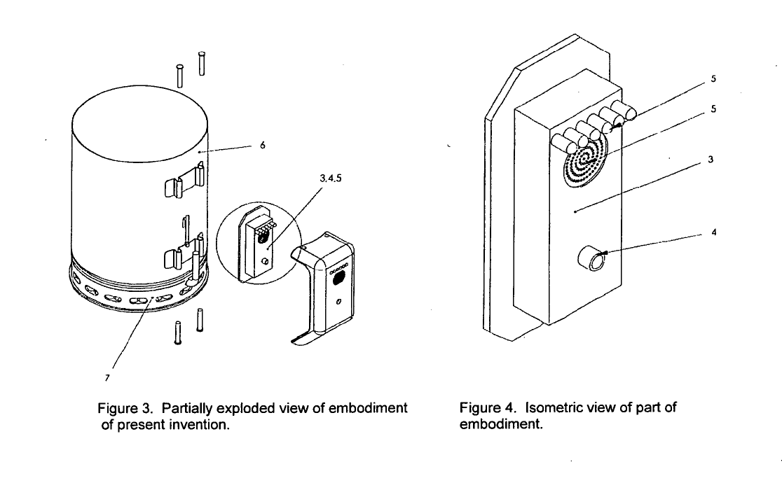

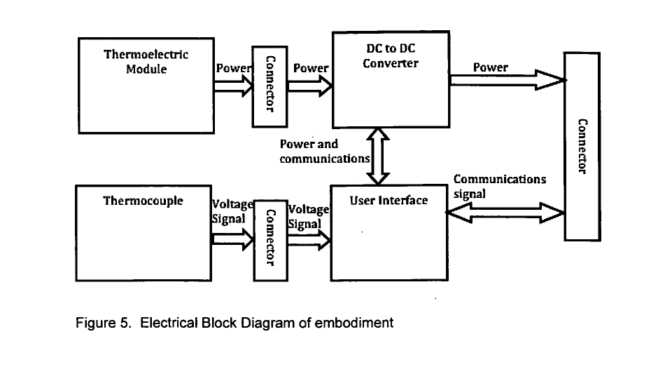

We claim:

1. A device utilizing a vessel of liquid and a heat source to provide electricity, comprising:
a thermoelectric module, adapted to be inserted between the vessel of liquid and a heat sink;
a heat sink adapted to be thermally coupled to the thermoelectric module and mechanically coupled to the vessel;
an electrical insulator and thermal conductor between the vessel and the thermoelectric module and between the thermoelectric module and the heat sink;
a thermocouple, that produces a voltage that changes with temperature;
a handle which mechanically couples to the vessel and the thermoelectric module;
a direct current to direct current converter, electrically coupled to the thermoelectric module and housed in the handle;
a user interface electrically coupled to the thermocouple and direct current to direct current converter and housed in the handle;
a connector, housed in the handle and electrically coupled to the direct current to direct current converter and the user interface, to provide electricity from the direct current to direct current converter to an external electrical device and to provide communication between the user interface and an external electrical device;
and, a communication signal transmitting and receiving information via said connector or an additional connector to an external electrical device.

2. The vessel defined in claim 1, comprising a cavity for holding liquid and an attachment mechanism wherein said handle may be mechanically attached or detached.

3. The vessel defined in claim 1, comprising an attachment mechanism wherein said heat sink may be mechanically attached or detached and which provides mechanical pressure applied upon said thermoelectric module to said vessel.

4. The thermoelectric module defined in claim 1, comprising: junctions of dissimilar material which produce electrical power with an applied temperature difference across its body; an electrical coupling to said direct current to direct current converter.

5. The electrical coupling defined in claim 4, comprising wires and/or an electrical connector.

6. The heat sink defined in claim 1, comprising: a flat surface thermally coupled to the thermoelectric module; an attachment mechanism which mates to the vessel defined in claim 3 and provides mechanical pressure and improves thermal conductivity between the heat source and said thermoelectric module; and heat fins extending opposite the flat surface and absorbing thermal energy from the heat source and improving thermal conductivity between the heat source and said thermoelectric module.

7. The electrical insulator and thermal conductor defined in claim 1, comprising: a ceramic wafer adapted to be inserted between the vessel and the thermoelectric module and between the thermoelectric module and the heat sink; anodized aluminum or titanium applied on the vessel and heat sink; and thermally conductive grease applied on the vessel and heat sink.

8. The thermocouple defined in claim 1, adapted to be inserted against the vessel, the thermoelectric module, or heat sink and electrically coupled to the user interface.

9. The handle defined in claim 1, comprising: an attachment mechanism which mates to the vessel defined in claim 2; an internal cavity wherein said direct current to direct current converter, said user interface, said connector defined in claim 1, and a mating electrical connector coupling said connector defined in claim 5 to said direct current to direct current converter and said user interface are housed.

10. The direct current to direct current converter defined in claim 1, comprising: one or more buck, boost, buck-boost, flyback, push-pull, single ended primary inductor converter (SEPIC), Cuk, forward, half-bridge, full-bridge, resonant, or any other converter; a method whereby the power output of said thermoelectric module may be optimized; a method whereby the efficiency of said thermoelectric module may be optimized; a mating electrical connector coupling the direct current to direct current converter to said thermoelectric module defined in claim 5; an electrical coupling to said connector defined in claim 1; and an electrical coupling to the user interface.

11. The method of optimizing output power defined in claim 10, comprising: operation of said direct current to direct current converter in voltage mode control and/or current mode control whereby the output current is limited at the maximum output power of said thermoelectric module; operation of said direct current to direct current converter by a maximum power point tracking algorithm method whereby the output power of said thermoelectric module is maximized.

12. The method of optimizing efficiency defined in claim 10, comprising: operation of said direct current to direct current converter in voltage mode control and/or current mode control whereby the output current is limited at the maximum efficiency of said thermoelectric module; operation of said direct current to direct current converter by a power point tracking algorithm method whereby said thermoelectric module efficiency is maximized.

13. The connector defined in claim 1, comprising one or more electrical connectors coupled to said direct current to direct current converter and/or the user interface, to provide electricity from said direct current to direct current converter to an external electrical device and to transmit and receive said communication signal to an external electrical device.

14. The user interface defined in claim 1, comprising: analog and/or digital logic circuits electrically coupled to said connector defined in claim 13, said thermocouple, said direct current to direct current converter,
an electronic display, and/or a speaker; a logical circuit and/or algorithm wherein operating conditions of the invention are processed and displayed or sounded via said electronic display and/or speaker; a logical circuit and/or algorithm wherein said communication signal is transmitted and received via said connector defined in claim 13.

15. The communication signal defined in claim 1, comprising: an electrical data protocol whereby information is transmitted and received between circuits of the user interface and an external electrical device.
